(19) United States
(12) Patent Application Publication
(10) Pub. No.: US 2025/0314240 A1
(43) Pub. Date: Oct. 9, 2025

(54) SENSING WITHIN A SUBSEA ELECTRIC ARCHITECTURE IN A WIND FARM

(71) Applicant: Equinor Energy AS, Stavanger (NO)

(72) Inventors: Vegard NEDREVÅG, Oslo (NO); Øyvind Holm SNEFJELLÅ, Trondheim (NO); Arild LANGE, Oslo (NO)

(73) Assignee: Equinor Energy AS, Stavanger (NO)

(21) Appl. No.: 18/881,615

(22) PCT Filed: Jul. 3, 2023
(86) PCT No.: PCT/NO2023/060009

§ 371 Date: Jan. 6, 2025

(30) Foreign Application Priority Data
Jul. 5, 2022 (GB) 2209858.6

(51) Int. Cl. F03D 17/00; G01R 19/165; G01R 31/08

(52) U.S. Cl. CPC F03D 17/003; G01R 19/16538; G01R 31/083

(57) ABSTRACT

A system for monitoring properties within a subsea electrical architecture of an offshore windfarm including one or more wind turbines incudes first passive optical sensors within the subsea unit for monitoring an electrical or environmental property within the subsea unit, a first optical fibre bundle extending integrally within a power cable, a first optical interconnection unit within the subsea unit and optically coupling one or more optical fibres of the optical fibre bundle to the passive optical sensors, a monitoring unit located at an onshore grid connection point, and a second optical interconnection unit optically coupling one or more optical fibres of the optical fibre bundle to said monitoring unit. The monitoring unit is configured to transmit monitoring light signals along one or more optical fibres of the first optical fibre bundle to said first optical interconnection unit and to localise a fault and/or operate a circuit breaker in dependence upon optical signals transmitted from the or each first passive optical sensor over the first optical fibre bundle.

### TECHNICAL FIELD

The present invention relates to sensing within a subsea electric architecture in a wind farm and in particular, though not necessarily, to the subsea sensing of electrical current, voltage, power, and temperature, and subsea sensing to facilitate fault localization within such an architecture.

### BACKGROUND

Offshore wind farms are playing an ever increasing role in supplying electrical energy. This is driven by the increasing capacity of wind turbines and the increasing numbers of turbines in individual wind farms. Considering for example the Dogger Bank wind farm located off the north east coast of England, this is projected to have a generating capacity of 3.6 GW produced by around 600 individual turbines.

Within a given wind farm, the individual turbines, or subsets of those turbines, may be connected to a substation which delivers power to an onshore grid connection point via a main power supply or “export” cable. Power may be transferred from the substation to the onshore grid connection point via AC transmission or via High Voltage DC (HVDC) transmission. The turbines themselves generate AC power and this power is transferred from the turbines to the substation for conversion to DC and/or to step up or down the voltage. The substation utilises transformers and/or DC to AC converters before transferring the power over the export cable. Whilst the export cable will be a submarine power cable, the substation may be located above the water level or subsea, typically on the seabed.

FIG. 1 illustrates an exemplary electrical connection architecture for a wind farm 1. In this architecture, groups of four wind turbines 2 are coupled to respective junction 3 boxes in a “star” configuration, i.e. in parallel, via respective local cables 4. A single cable 5 (sometimes referred to as a “collector” cable) connects each junction box 3 to the offshore substation 6 and, via that substation, to the export cable 7. As of today, architectures with topside, bottom-fixed substations, have been deployed. An alternative architecture, possible when the windfarm is located relatively close to shore, allows the collector cable to extend directly to shore, avoiding the need for a topside substation.

It is of course conceivable that both the junction box and the substation may be located subsea. In this case, and assuming the illustrated star configuration, cables 4,5 may be connected to the junction box 3 with a wet mate connector (not shown in the Figure). Wet mate connectors allow the underwater connection and disconnection of components and cables, avoiding the need to bring these components and cables to the surface for connection making the process cheaper and quicker. A wet mate connector can be connected and disconnected subsea using a Remotely Operated Vehicle (ROV) or other means. It may be possible to insert a blind plug/cap in place of one of the cable connectors-half, and hence run power through the subsea junction box with one or more of the cables disconnected. Some connectors may also allow a voltage to be applied to them without a protection cap (as they have built in protection/barrier). Cables 5,7 may be similarly connected to the substation 6 using wet mate connectors.

Other connection architectures are of course possible. By way of example, FIG. 2 illustrates a set of wind turbines connected in a “daisy chain” manner, i.e. in series, whilst FIG. 3 illustrates two pairs of wind turbines, with the turbines of each pair being connected in parallel to a subsea junction box, and the junction boxes being connected in series to the collector cable. In a modified implementation of the architecture of FIG. 3, the wind turbines are connected n series, each wind turbine being connected to the collector cable via a T-junction.

The subsea junction box 3 and substation 6 may have integrated electrical breakers or disconnectors and may have control features for operation of these mechanical devices. They may have sensing means for monitoring of current and of the flow of power or monitoring of other aspects of the plant and may have features for fault identification and localization.

The subsea substation 6 may also include control and monitoring features for the substation itself, for the connected subsea power cables 5,7 and for the wind turbines 2. The monitoring features may be used to identify and locate failures in the subsea electrical network, including cables, connectors, subsea junction box and subsea substation. The control and monitoring system may be coordinated with the control and protection system in the wind turbines and the one on the receiving end of the export cable, ensuring selectivity.

Conventional electrical sensors used for protection and monitoring, e.g. current and voltage transformers, Rogowski coils and voltage dividers, require a protection relay or a similar interface unit in close proximity. These devices require a low voltage power supply and power supply connection, and they are expected to have a lower reliability than the sensors themselves. Of course, transferring low voltage power over long distances is often not feasible. While circuit breakers, protection relays can be and indeed are provided onshore, the absence of these within the subsea components makes it challenging to identify, localize and clear/isolate faults in the electrical network.

In the case of subsea junction boxes and substations that do not have integrated circuit breakers, circuit breakers need to be located onshore. The absence of local, subsea circuit breakers and their associated protection relays is problematic however when seeking to implement sensors by means of conventional current transformers and voltage transformers

### SUMMARY

It is an object of the present invention to reduce or preferably eliminate the need for active, i.e. powered, components within the subsea units, for example subsea junction boxes and substations. This is achieved by introducing passive, optical sensors into the units. Local, low voltage power supplies and associated power supply connections are no longer required, reducing cost and complexity. Switchgear, including circuit breakers and protection relays, may be located onshore.

According to a first aspect of the present invention there is provided a system for monitoring properties within a subsea electrical architecture of an offshore windfarm comprising one or more wind turbines electrically coupled to at least one subsea unit and the subsea unit being coupled, via a power cable, to an offshore topside, bottom-fixed unit or to an onshore grid connection point for transmitting electrical power generated by the or each wind turbine. The system comprises one or more first passive optical sensors within the subsea unit for monitoring an electrical or environmental property within the subsea unit, a first optical fibre bundle extending integrally within, or in proximity to, the power cable, a first optical interconnection unit within the subsea unit and optically coupling one or more optical fibres of the optical fibre bundle to the or each first passive optical sensor, a monitoring unit located at or in proximity to said offshore topside, bottom-fixed unit or to said onshore grid connection point, and a second optical interconnection unit optically coupling one or more optical fibres of the optical fibre bundle to said monitoring unit. The monitoring unit is configured to transmit monitoring light signals along one or more optical fibres of the first optical fibre bundle to said first optical interconnection unit and to localise a fault and/or operate a circuit breaker in dependence upon optical signals transmitted from the or each first passive optical sensor over the first optical fibre bundle.

The subsea unit may be one of a junction box and a substation. Where the subsea unit is a subsea substation and said power cable is a main export power cable connected to said grid connection point, the monitoring unit and said second optical interconnection unit may be located at or proximity to said grid connection point.

The system may comprise at least one second subsea unit, the second subsea unit being a junction box connected by a local cable to a wind turbine and to said subsea substation by a collector cable, the system further comprising one or more second passive optical sensors within the junction box for monitoring an electrical or environmental property within the junction box, a second optical fibre bundle extending integrally within, or in proximity to, the collector cable, and a second optical interconnection unit within the junction box and optically coupling one or more optical fibres of the second optical fibre bundle to the or each second passive optical sensor. The first optical interconnection unit within the subsea substation optically couples fibres of the first and second optical fibre bundles, and said monitoring unit is further configured to cause monitoring light signals to be transmitted along one or more optical fibres of the second optical fibre bundle to said second passive optical sensors and to localise a fault and/or operate a circuit breaker in dependence upon optical signals transmitted from the or each second passive optical sensor over the second optical fibre bundle.

Where said first subsea unit is a subsea junction box coupled by a collector power cable to an offshore topside, bottom-fixed unit, the offshore topside, bottom-fixed unit may be a substation and having a source of low voltage power for said monitoring unit.

The or each first and/or second passive optical sensor may be configured to sense one of current, voltage, power and temperature, and said monitoring unit may be configured to perform a fault localisation and/or operate a circuit breaker in the event that an optical signal transmitted from the or each first or second passive optical sensor is indicative of a current, voltage, power or temperature outside of a predefined operating range, for example exceeding a predefined threshold.

The or each subsea unit may be filled with oil under pressure.

The or each power cable may be one of a 3 phase AC submarine power cable and a High Voltage DC, HVDC, submarine power cable.

The or each passive optical sensor may be a discrete optical sensor or a distributed optical sensor.

The or each passive optical sensor may be configured to monitor an electrical or environmental property within the subsea unit associated with a corresponding electrical component, the component having a dynamic electrical rating.

According to a second aspect of the present invention there is provided a method of monitoring properties within a subsea electrical architecture of an offshore windfarm comprising one or more wind turbines electrically coupled to at least one subsea unit and the subsea unit being coupled, via a power cable, to an offshore topside, bottom-fixed unit or to an onshore grid connection point for transmitting electrical power generated by the or each wind turbine. The method comprises transmitting monitoring light signals from a monitoring unit, along one or more optical fibres of a first optical fibre bundle extending integrally within, or in proximity to, the power cable, receiving the monitoring light signals at a first optical interconnection unit within the subsea unit and optically coupling the signals to one or more first passive optical sensors within the subsea unit, the sensors configured to monitor an electrical or environmental property within the subsea unit, returning light signals from the or each sensor, via the first optical interconnection unit and one or more optical fibres of the first optical fibre bundle, to said monitoring unit, and analysing the returned light signals to localise a fault and/or operate a circuit breaker.

### BRIEF DESCRIPTION OF THE DRAWINGS

FIG. 1 illustrates schematically an electrical architecture for an offshore wind farm with subsets of wind turbines coupled in a star configuration and with the subsets coupled in parallel to a subsea substation;

FIG. 2 illustrates a set of wind turbines connected in a daisy chain configuration;

FIG. 3 illustrates two pairs of wind turbines coupled in series to a subsea substation;

FIG. 4 illustrates exemplary 3 phase AC and HVDC submarine power cables;

FIG. 5 illustrates schematically an offshore windfarm electrical architecture making use of passive optical sensors; and

FIG. 6 illustrates schematically various exemplary electrical architecture schemes.

### DETAILED DESCRIPTION

It will be appreciated that it is desirable to operate various sensors at subsea locations within an offshore wind farm electrical architecture. However, where these sensors require (low voltage) electrical power, supplying that power, especially over long distances, e.g. from an onshore location or a topside offshore location, can be challenging and expensive. It is therefore proposed to implement sensors for monitoring current, voltage, power (by way of current and voltage measurements), temperature and for fault localization, within subsea units, as passive optical sensors communicating directly over fibre optic communication, eliminating the need for active sensors and an associated auxiliary/control power supply. Fibre optic cables are able to run over great lengths, for example, up to several hundred kilometres, without the need for repeaters. As such, it is possible to operate such passive sensors from an onshore location or offshore topside without the need for any offshore power or otherwise locally generated offshore power. Multiple fibre optic cables may be run as a single bundle from the onshore location or offshore topside location. Components of the electrical architecture such as the subsea substation or subsea junction box may include a fibre optic cable distribution means, distributing the individual fibre optic cables in a single bundle within the component and/or for running over further cables. Circuit breakers associated with the wind farm and the subsea cables may be located onshore or at an offshore topside location.

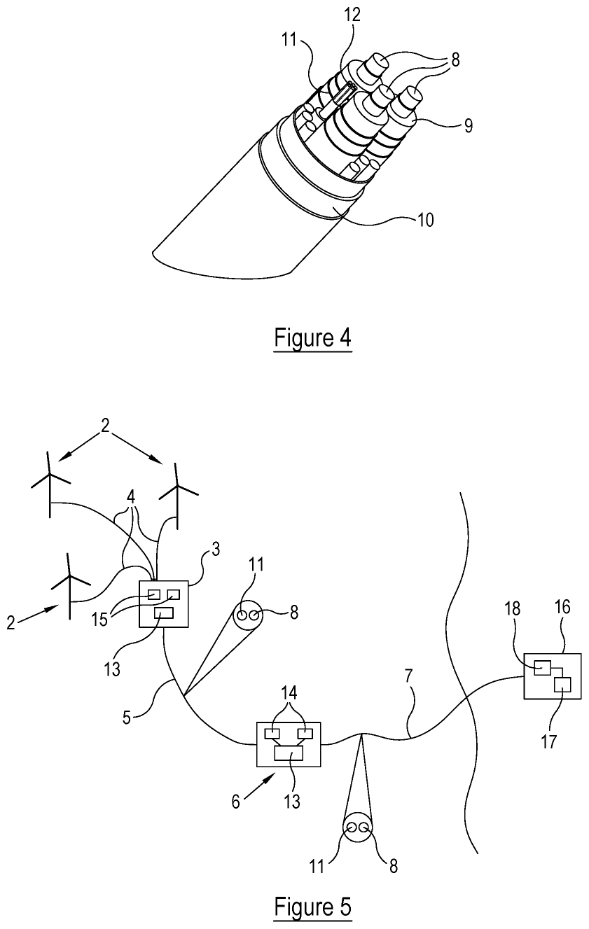

Whilst running fibre optic cables over significant distances may present problems, these can be mitigated by utilising submarine cables integrating AC and fibre optic cable bundles, or in the case of HVDC, utilising fibre optic cable bundles laid in proximity to the HVDC power cables. Such submarine AC cables are conventionally used for providing power to offshore facilities, e.g. oil and gas production platforms, but can be used for the primary purpose of transferring power within a wind farm electrical architecture to an onshore grid connection location. FIG. 4 illustrates schematically an exemplary 3 phase AC submarine power cable including three main power lines 8 with associated insulation 9 and outer armour and protection layers 10. Included within the cable is a fibre optical cable bundle 11 including multiple optical fibres 12. It is therefore proposed to use such optical fibre bundles as the means to operate and interrogate passive sensors within the wind farm electrical architecture.

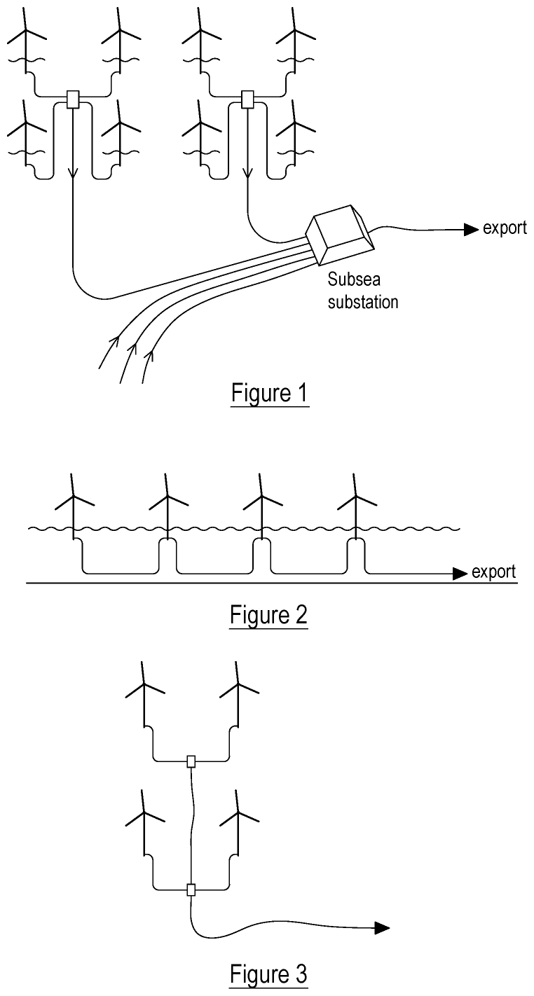

FIG. 5 illustrates an exemplary wind farm electrical architecture based on the architecture of FIG. 1 but utilising optical fibre bundles incorporated into the main export cable 7 and into the collector cable 5 connecting the subsea junction box 3 to the subsea substation 6. The collector cable and main export cable may have the same or different constructions but both incorporate an optical fibre bundle 11.

The subsea junction box 3 and the subsea substation 6 both incorporate optical interconnects 13 that facilitate passive routing of optical signals from individual optical fibres 12 of the respective bundles, either to other optical components, e.g. optical sensors, within the junction box or substation or across the junction box or substation for connection to an optical fibre of an outgoing fibre bundle. In the latter case, this may be to facilitate routing of an optical signal, at a subsea substation, between a fibre of the export cable and a fibre of the collection cable. By way of example, the fibre optic bundle in the export cable may include 48 fibres encapsulated in one common metallic tube. The 48 fibres are then distributed to the respective collector cables, e.g. in the case of 4 collector cables, 12 fibres will be routed to each collector cable. NB. A single optical fibre may be interfaced to multiple passive optical sensors. In the case of temperature sensing, the temperature may be sensed directly from the fibre, reading the temperature profile along a length of the fibre.

Considering now a passive optical sensor 14,15 located within the subsea junction box or subsea substation, the proposed architecture allows essentially for a direct connection to an onshore substation 16. In the onshore substation 16, signals will be connected to protection relays such that a subsea fault, via some monitoring unit 18, may trigger opening of an onshore circuit breaker 17. Alternatively, or in addition, measurements will be used to localize the fault such that a vessel may be mobilized to visit the site and perform an inspection and, if necessary, a “repair”, for example by disconnecting a faulty component or unit by way of a wet mate connector to enable the wind farm to continue operation, possibly with reduced capacity. The proposed architecture avoids the need for any circuit breakers in the subsea substation or subsea junction box and hence avoids the need for power at these locations.

Passive optical sensors suitable for monitoring currents and voltages include, for example, those supplied by Synaptec™, Glasgow, UK. However, to the best of the inventors' knowledge, the use of such sensors at a subsea location has not previously been proposed. Although it is not necessary to provide a detailed description of optical sensors here, these generally operate in close vicinity to a power cable, e.g. wound around the power cable as a series of turns, on which a voltage and/or current measurement is to be made such that the electromagnetic field surrounding the power cable influences light travelling along an optical component, e.g. a fibre, typically modulating the intensity or frequency of the light. Light returned to the onshore monitoring station, e.g. along the same fibre(s) used to transmit the light to the sensor or along a different fibre(s) is demodulated to identify the modulating signal and thereby determine the current and/or voltage on the power cable. By inspecting the measured current, voltage or temperature, a fault may be detected and localised, and action taken. Passive optical sensors may also be used to measure temperature on a cable within the subsea junction box or subsea substation or at some other location within the junction box or subsea substation. Use of such a passive temperature sensor may be used for “dynamic rating” of a component, e.g. a subsea transformer in the subsea substation, allowing the component to be operated above rated power for limited periods.

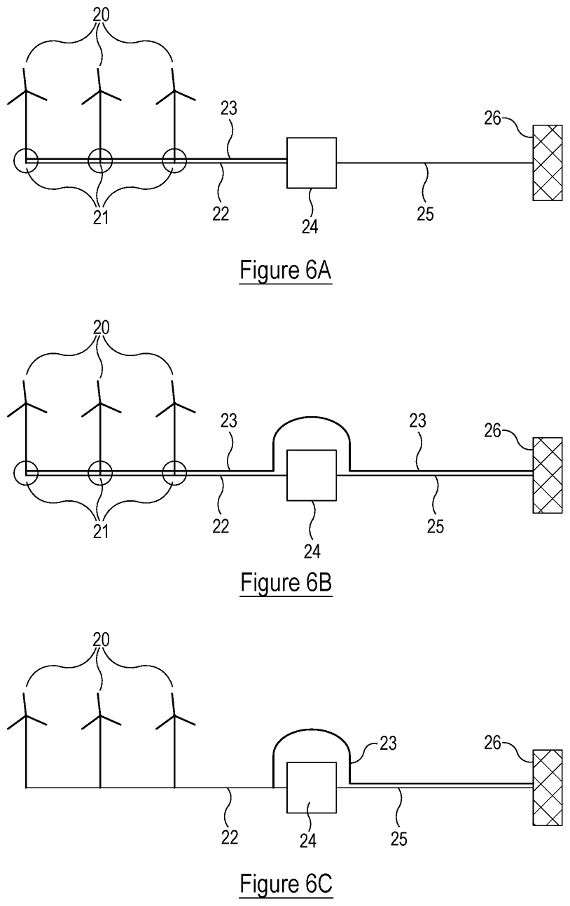

It will be appreciated that various modifications may be made to the above described embodiments without departing from the scope of the present invention. In particular, whilst FIG. 5 illustrates a relatively complex scheme, other schemes are possible which utilise passive optical sensors integrated into subsea units and long or short run optical fibre bundles. For example, FIG. 6A illustrates a scheme in which a number of wind turbines 20 are connected to respective subsea junction boxes 21 and via the junction boxes to a collector cable 22. The collector cable includes an integrated optical fibre bundle 23, or an optical fibre bundle laid with or in proximity to the collector cable. The optical fibre bundle 23 is coupled to passive sensors within the junction boxes 21, and terminates at a topside, bottom-fixed substation 24 which comprises means for transmitting and monitoring optical signals along the fibre bundle for the purpose of localising faults and/or operating circuit breakers. The topside substation 24 is coupled to a grid connection point 26 by a main export cable 25. As the substation is a topside substation, low voltage power is available at the substation.

FIG. 6B illustrates a scheme not dissimilar to that of FIG. 5, with the optical fibre bundle 23 extending from the onshore grid connection point, through a subsea substation, to subsea junction boxes, with passive sensors located within the subsea junction boxes and the substation. In this case, the optical fibre bundle 23 is integrated into, or laid with or in proximity to, both the collector cable 22 and the main export cable 25.

FIG. 6C illustrates yet another scheme in which the substation is again a subsea substation 24 containing passive optical sensors, the passive optical sensors being coupled to optical fibres of a fibre bundle 23 extending from the onshore grid connection point 26.

1. A system for monitoring properties within a subsea electrical architecture of an offshore windfarm comprising one or more wind turbines electrically coupled to at least one subsea unit and the subsea unit being coupled, via a power cable, to an offshore topside, bottom-fixed unit or to an onshore grid connection point for transmitting electrical power generated by the or each wind turbine, the system comprising:
one or more first passive optical sensors within the subsea unit for monitoring an electrical or environmental property within the subsea unit;
a first optical fibre bundle extending integrally within, or in proximity to, the power cable;
a first optical interconnection unit within the subsea unit and optically coupling one or more optical fibres of the optical fibre bundle to the or each first passive optical sensor;
a monitoring unit located at or in proximity to said offshore topside, bottom-fixed unit or to said onshore grid connection point;
a second optical interconnection unit optically coupling one or more optical fibres of the optical fibre bundle to said monitoring unit,
wherein said monitoring unit is configured to transmit monitoring light signals along one or more optical fibres of the first optical fibre bundle to said first optical interconnection unit and to localise a fault and/or operate a circuit breaker in dependence upon optical signals transmitted from the or each first passive optical sensor over the first optical fibre bundle.

2. The system according to claim 1, wherein said subsea unit is one of a junction box and a substation.

3. The system according to claim 1, wherein said subsea unit is a subsea substation and said power cable is a main export power cable connected to said grid connection point, wherein said monitoring unit and said second optical interconnection unit are located at or proximity to said grid connection point.

4. The system according to claim 2 and comprising at least one second subsea unit, the second subsea unit being a junction box connected by a local cable to a wind turbine and to said subsea substation by a collector cable, the system further comprising:
one or more second passive optical sensors within the junction box for monitoring an electrical or environmental property within the junction box;
a second optical fibre bundle extending integrally within, or in proximity to, the collector cable;
a second optical interconnection unit within the junction box and optically coupling one or more optical fibres of the second optical fibre bundle to the or each second passive optical sensor,
wherein said first optical interconnection unit within the subsea substation optically couples fibres of the first and second optical fibre bundles, and said monitoring unit is further configured to cause monitoring light signals to be transmitted along one or more optical fibres of the second optical fibre bundle to said second passive optical sensors and to localise a fault and/or operate a circuit breaker in dependence upon optical signals transmitted from the or each second passive optical sensor over the second optical fibre bundle.

5. The system according to claim 1, where said first subsea unit is a subsea junction box coupled by a collector power cable to an offshore topside, bottom-fixed unit, the offshore topside, bottom-fixed unit being a substation and having a source of low voltage power for said monitoring unit.

6. The system according to claim 1, wherein the or each first and/or second passive optical sensor is configured to sense one of current, voltage, power and temperature, and said monitoring unit is configured to perform a fault localisation and/or operate a circuit breaker in the event that an optical signal transmitted from the or each first or second passive optical sensor is indicative of a current, voltage, power or temperature outside of a predefined operating range, for example exceeding a predefined threshold.

7. The system according to ms claim 1, where the or each subsea unit is filled with oil under pressure.

8. The system according to claim 1, wherein the or each power cable is one of a 3 phase AC submarine power cable and a High Voltage DC, HVDC, submarine power cable.

9. The system according to claim 1, the or each passive optical sensor being a discrete optical sensor or a distributed optical sensor.

10. The system according to claim 1, the or each passive optical sensor monitoring an electrical or environmental property within the subsea unit associated with a corresponding electrical component, the component having a dynamic electrical rating.

11. A method of monitoring properties within a subsea electrical architecture of an offshore windfarm comprising one or more wind turbines electrically coupled to at least one subsea unit and the subsea unit being coupled, via a power cable, to an offshore topside, bottom-fixed unit or to an onshore grid connection point for transmitting electrical power generated by the or each wind turbine, the method comprising:
transmitting monitoring light signals from a monitoring unit, along one or more optical fibres of a first optical fibre bundle extending integrally within, or in proximity to, the power cable;
receiving the monitoring light signals at a first optical interconnection unit within the subsea unit and optically coupling the signals to one or more first passive optical sensors within the subsea unit, the sensors configured to monitor an electrical or environmental property within the subsea unit;
returning light signals from the or each sensor, via the first optical interconnection unit and one or more optical fibres of the first optical fibre bundle, to said monitoring unit; and
analysing the returned light signals to localise a fault and/or operate a circuit breaker.
